(19) United States
(12) Patent Application Publication
(10) Pub. No.: US 2020/0190665 A1
(43) Pub. Date: Jun. 18, 2020

(54) SiC CHEMICAL VAPOR DEPOSITION DEVICE

(71) Applicant: SHOWA DENKO K.K., Tokyo (JP)

(72) Inventors: Yoshikazu UMETA, Chichibu-shi (JP); Yoshishige OKUNO, Chiba-shi (JP); Rimpei KINDAICHI, Chiba-shi (JP)

(73) Assignee: SHOWA DENKO K.K., Tokyo (JP)

(21) Appl. No.: 16/710,550

(22) Filed: Dec. 11, 2019

(30) Foreign Application Priority Data
Dec. 17, 2018 (JP) 2018-235553

(51) Int. Cl. C23C 16/44; C23C 16/32

(52) U.S. Cl. CPC C23C 16/44; C23C 16/325

(57) ABSTRACT

A SiC chemical vapor deposition device according to the present embodiment includes a placement table on which a SiC wafer is placed; and a furnace body that covers the placement table, in which the furnace body has a side wall and a ceiling that has a gas supply port for supplying raw material gas to the inside of the furnace body, covers a periphery of the gas supply port, and is positioned above the placement table, and emissivity of an inner surface of the ceiling is lower than that of an inner surface of the side wall.

### BACKGROUND OF THE INVENTION

### Field of the Invention

The present invention relates to a SiC chemical vapor deposition device.

Priority is claimed on Japanese Patent Application No. 2018-235553, filed on Dec. 17, 2018, the contents of which are incorporated herein by reference.

### Description of Related Art

Silicon carbide (SiC) has characteristics of having a larger breakdown electric field by one digit, having a band gap three times larger, and thermal conductivity about three times higher than those of silicon (Si). Therefore, silicon carbide (SiC) is expected to be applied to a power device, a high frequency device, a high temperature operation device, and the like.

To promote the practical application of SiC devices, it is essential to establish high quality SiC epitaxial wafers and high quality epitaxial growth technologies.

An SiC device is manufactured with a SiC epitaxial wafer which is obtained by growing an epitaxial film, which acts an active region of a device, by chemical vapor deposition (CVD) or the like on a SiC wafer, which is obtained by processing a SiC bulk single crystal which is grown by a sublimation recrystallization method or the like. In the present specification, a SiC epitaxial wafer means a wafer obtained after an epitaxial film is formed on a SiC wafer, and a SiC wafer means a wafer on which an epitaxial film is not formed.

The epitaxial film is obtained by recrystallization of the raw material gas near the SiC wafer. The temperature in a furnace when the epitaxial film is formed reaches an extremely high temperature of about 1,500° C. (for example, Patent Document 1).

### Patent Document 1: Japanese Unexamined Patent Application, First Publication No. 2016-25309

### SUMMARY OF THE INVENTION

In order to maintain the inside of a furnace at the film formation temperature of the epitaxial film, much electric power is required. The power consumption has a great influence on the manufacturing cost of SiC epitaxial wafers. Accordingly, there is a demand for lower power consumption of the SiC epitaxial manufacturing device.

The present invention has been made in view of the above problems, and an object thereof is to obtain a SiC chemical vapor deposition device having excellent power consumption.

As a result of intensive studies, the present inventors found that, only by changing the emissivity of a predetermined portion of the furnace body, the heating efficiency of the SiC wafer can be improved and the lower power consumption of the SiC epitaxial manufacturing device can be realized.

That is, the present invention provides the following means in order to solve the above object.

(1) A SiC chemical vapor deposition device according to a first aspect includes a placement table on which a SiC wafer is placed; and a furnace body that covers the placement table, in which the furnace body has a side wall, a ceiling that has a supply port for supplying raw material gas to the inside of the furnace body, covers a periphery of the supply port, and is positioned above the placement table, and a tapered part that connects together the ceiling and the side wall, and emissivity of inner surfaces of the ceiling and the tapered part is lower than that of an inner surface of the side wall.

The SiC chemical vapor deposition device according to the first aspect preferably includes the following characteristics. It is preferable that one or more of the following characteristics are combined with each other.

(2) In the SiC chemical vapor deposition device according to the above aspect, inner surfaces of the ceiling and the tapered part may be coated with TaC.

(3) In the SiC chemical vapor deposition device according to the above aspect, the inner surface of the side wall may be coated with SiC.

(4) The SiC chemical vapor deposition device according to the above aspect further includes a heater that surrounds an outer periphery of the side wall in a circumferential direction with an axis which is an imaginary line connecting the placement table and the ceiling, and an upper end of the heater is placed at a lower position than the ceiling and the tapered part.

The SiC chemical vapor deposition device according to the first aspect of the present invention is excellent in power consumption.

### BRIEF DESCRIPTION OF THE DRAWINGS

FIG. 1 is a schematic view showing a preferable example of an SiC chemical vapor deposition device according to a first embodiment.

FIG. 2 is a view schematically showing multiple reflections of radiant heat (electromagnetic waves) in a film formation space.

FIG. 3 is a view showing a simulation result according to Example 1.

FIG. 4 is a view showing a simulation result according to Comparative Example

FIG. 5 is a view showing a simulation result according to Comparative Example 2.

### DETAILED DESCRIPTION OF THE INVENTION

Hereinafter, a preferable example of the SiC chemical vapor deposition device according to the present embodiment is described in detail with reference to the drawings as appropriate. In the drawings used in the following description, in order to make the characteristics of the present invention easier to understand, the characteristic parts may be enlarged for the sake of convenience, and thus the dimension and ratios of the respective components may be different from actual values. The materials, dimensions, and the like exemplified in the following description are examples, and the present invention is not limited thereto and can be appropriately modified and implemented without changing the gist thereof. That is, the position, number, shape, material, configuration, and the like can be added, omitted, substituted, or changed without departing from the gist of the present invention.

Directions are defined. The +z direction is a direction perpendicular to a placement surface 20a on which the wafer is placed and is a direction directing to the ceiling 11 described below. The −z direction is opposite to the +z direction. When the directions are not distinguished, the directions are simply expressed as a “z direction”. The +z direction may be referred to as “above”, and the −z direction may be referred to as “below”. The x direction is a certain direction orthogonal to the z direction. The y direction is a direction orthogonal to the x direction and the z direction.

### First Embodiment

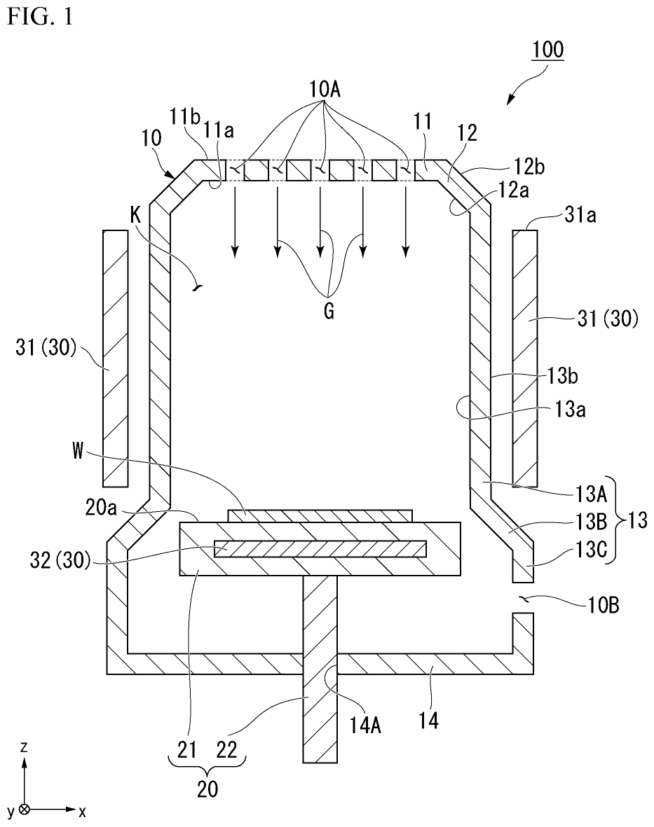

FIG. 1 is a schematic cross-sectional view showing a preferable example of the SiC chemical vapor deposition device 100 according to the first embodiment. FIG. 1 simultaneously shows a SiC wafer W which is used for forming a SiC epitaxial film.

The SiC chemical vapor deposition device 100 includes a furnace body 10, a placement table 20, and a heater 30.

(Furnace Body)

The furnace body 10 includes a ceiling 11, a tapered part 12, a side wall 13, and a bottom part 14. The furnace body 10 has a film formation space K therein.

The ceiling 11 is a portion that is placed above the placement table 20 and is substantially parallel to the placement surface 20a of the placement table 20. The ceiling 11 faces the placement surface 20a. It is also preferable that the ceiling 11 and the placement surface 20a are parallel to each other.

The ceiling 11 has supply ports 10A that supply raw material gas G into the furnace body 10. The raw material gas G reacts on the SiC wafer W to form an epitaxial film. The raw material gas G can be optionally selected, and, for example, Si-based gas and C-based gas can be used. Examples of Si-based gases include silane (SiH₄), dichlorosilane (SiH₂Cl₂), trichlorosilane (SiHCl₃), and tetrachlorosilane (SiCl₄). The C-based gas is, for example, propane (C₃H₈). These gases may be used singly or in combination. The raw material gas G may include etching gas (for example, HCl), carrier gas (for example, Ar), dopant gas (for example, N₂ or trimethylaluminum (TMA) and the like, in addition to Si-based gas and C-based gas.

The ceiling 11 has an inner surface 11a and an outer surface 11b. The inner surface 11a is a surface that is on the inner side of the furnace body 10 and is exposed to the film formation space K. The outer surface 11b is a surface that is on a side opposite to the inner surface 11a and is exposed to the outside. The emissivity of the inner surface 11a is lower than that of an inner surface 13a of the side wall 13 described below. The emissivity of the inner surface 11a is preferably 0.5 or less, more preferably 0.3 or less, and even more preferably 0.2 or less. The lower limit of the emissivity of the inner surface 11a can be optionally selected, but, for example, may be 0.001, 0.01, or 0.1. The emissivity of the outer surface 11b is not particularly limited.

The emissivity is also called a radiation rate. The radiation rate is a rate of the energy, which is radiated by an object by heat radiation, to the energy, which is radiated by a black body which has the same temperature, that is, the complete radiator, and the latter energy is assumed to be 1. When the emissivity (radiation rate) is high, heat is easily received, and when the emissivity (radiation rate) is low, heat is hardly received.

For example, the plurality of supply ports 10A may be present in the ceiling 11. The area ratio of the supply ports 10A with respect to the area of the ceiling 11 can be optionally selected, but is preferably 0.3 or less. The area ratio may be 0.25 or less or 0.15 or less. The lower limit of the area ratio can be optionally selected, and may be, for example, 0.01 or 0.05. Here, the “area of the ceiling 11” is an area of a region surrounded by the outer periphery of the ceiling 11 in a plan view from the z direction, and includes the area of the supply ports 10A. The “area of the supply ports 10A” is the total area of open regions in a plan view from the z direction. As the surface area of the ceiling 11 increases, the effective emissivity of the ceiling 11 decreases. When the area ratio of the supply ports 10A is within a predetermined range, increasing of the effective emissivity of the ceiling 11 can be suppressed.

The ceiling 11 is made of a material that has heat resistance to high temperatures which exceed 1,500° C., and has low reactivity with the raw material gas G. The ceiling 11 can be made of, for example, Ta, TaC, or TaC-coated graphite, or metal (for example, TaC-coated stainless steel (SUS)). The ceiling 11 is preferably TaC coated. In the case of TaC coated ceiling, the inner surface 11a of the ceiling 11 is coated. In the film formation temperature region, the emissivity of TaC and TaC-coated carbon is about 0.2 to 0.3, and the emissivity is low.

The tapered part 12 is a portion that connects together the ceiling 11 and the side wall 13. The outer diameter of the ceiling 11 is narrower than the outer diameter of the side wall 13. The diameter of the tapered part 12 increases in the −z direction from the ceiling 11.

The tapered part 12 has an inner surface 12a and an outer surface 12b. The inner surface 12a is a surface that is on the inner side of the furnace body 10 and is exposed to the film formation space K. The outer surface 12b is a surface that is positioned on a side opposite to the inner surface 12a and is exposed to the outside. The emissivity of the inner surface 12a is lower than that of the inner surface 13a of the side wall 13 described below. The emissivity of the inner surface 12a is preferably 0.5 or less, more preferably 0.3 or less, and even more preferably 0.2 or less. The lower limit of the emissivity of the inner surface 12a can be optionally selected, but for example, may be 0.001, 0.01, or 0.1. The emissivity of the outer surface 12b is not particularly limited.

For the tapered part 12, a material which is similar to that used for the ceiling 11 can be preferably used. The tapered part 12 may be Ta, TaC, or TaC-coated graphite or metal. For example, the inner surface 12a of the tapered part 12 is preferably coated with TaC.

The inner surface of the ceiling 11 and the inner surface of the tapered part 12 may have the same emissivity. Otherwise, the emissivity may be different from each other, and for example, the emissivity of the inner surface of the ceiling 11 may be higher or lower than that of the inner surface of the tapered part 12.

The side wall 13 is a portion surrounding the periphery of the central axis. The central axis is an axis that passes through the center of the SiC wafer W and extends in the z direction. The side wall 13 shown in FIG. 1 has a first portion 13A, a second portion 13B, and a third portion 13C in this order.

The first portion 13A is placed at an upper position than the SiC wafer W which is placed on the placement surface 20a. The inner diameter of the first portion 13A is slightly wider than the outer diameter of the placement surface 20a. The raw material gas G is supplied in a laminar flow to the SiC wafer W along the inner surface of the first portion 13A. The second portion 13B is a portion that connects between the first portion 13A and the third portion 13C. Diameter of the second portion 13B increases toward the −z direction. The unreacted raw material gas G or the like flows downward along the second portion 13B. The third portion 13C is placed at a lower position than the SiC wafer W which is placed on the placement surface 20a. The inner diameter of the third portion 13C is wider than that of the first portion 13A. The third portion 13C has an exhaust port 10B. The unreacted raw material gas G and the like are discharged from the exhaust port 10B.

The side wall 13 has the inner surface 13a and an outer surface 13b. The inner surface 13a is a surface that is on the inner side of the furnace body 10 and is exposed to the film formation space K. The outer surface 13b is a surface that is on a side opposite to the inner surface 13a and is exposed to the outside. The emissivity of the inner surface 13a and the outer surface 13b is higher than that of the inner surface 11a of the ceiling 11 and the inner surface 12a of the tapered part 12. The emissivity of the inner surface 13a and the outer surface 13b can be optionally selected as long as the above conditions are satisfied. For example, the emissivity of the inner surface 13a and the outer surface 13b may be 0.96 or less, or may be 0.9 or less, 0.8 or less, 0.7 or less, 0.5 or less, or 0.4 or less. The lower limit of the emissivity of the inner surface 13a and the outer surface 13b can be optionally selected, and for example, may be 0.001, 0.01, 0.1, 0.2, or 0.3.

The side wall 13 can be optionally selected, but is preferably coated with SiC. For example, the side wall is preferably made of a metal such as SiC-coated carbon or SiC-coated stainless steel. The emissivity of SiC is about 0.8.

The bottom part 14 is located at a position where the SiC wafer W is provided between the ceiling 11 and the bottom part 14. For example, the bottom part 14 is made of stainless steel, an aluminum alloy, or brass. The bottom part 14 has a hole 14A through which the support shaft of the placement table 20 passes.

(Placement Table)

The placement table 20 has the placement surface 20a on which the SiC wafer W is placed. The placement table 20 includes a support 21 and a support shaft 22. The support 21 supports the SiC wafer W. The support shaft 22 extends downward from the center of the support 21. For example, the support shaft 22 can be connected to a rotation mechanism (not shown). The support 21 can be rotated by rotating the support shaft 22 by a rotation mechanism. A second heater 32 described below can be stored inside the support 21.

(Heater)

The heater 30 includes a first heater 31 and the second heater 32. The first heater 31 surrounds the outer periphery of the side wall 13 in the circumferential direction. The first heater 31 extends in the z direction along the side wall 13.

An upper end 31a of the first heater 31 is placed at a lower position than the ceiling 11 and the tapered part 12. The second heater 32 is stored inside the support 21. Known heaters can be used for the first heater 31 and the second heater 32.

The SiC chemical vapor deposition device 100 according to the first embodiment can efficiently heat the SiC wafer W.

The first heater 31 heats the SiC wafer W through the furnace body 10. The side wall 13 receives radiation from the first heater 31. The side wall 13 has higher emissivity than the ceiling 11 and the tapered part 12 and easily absorbs electromagnetic waves. The side wall 13 efficiently receives the radiation from the first heater 31 and is heated.

The heated side wall 13 itself acts as a source of electromagnetic waves. The radiation from the side wall 13 spreads radially from the side wall 13. A part of the radiation from the side wall 13 reaches the SiC wafer W, and the SiC wafer W is heated. In addition to the SiC wafer W, a portion of the radiation from the side wall 13 reaches the ceiling 11 and the tapered part 12. The ceiling 11 and the tapered part 12 have low emissivity. Most of the electromagnetic waves reaching the ceiling 11 and the tapered part 12 are not absorbed but reflected. A part of the electromagnetic waves reflected by the ceiling 11 and the tapered part 12 reaches the SiC wafer W and heats the SiC wafer W.

That is, the SiC chemical vapor deposition device 100 prevents the radiation generated by the first heater 31 from being used for heating the ceiling 11 and the tapered part 12, and the SiC chemical vapor deposition device 100 efficiently heats the SiC wafer W.

Since the ceiling 11 and the tapered part 12 reflect much radiation, the temperature rise thereof is small. The ceiling 11 has the supply ports 10A from which the raw material gas G is supplied. The raw material gas G reacts and forms SiC, after the gas is decomposed in the furnace body 10. When the temperature of the supply port 10A is high, the raw material gas G is decomposed near the supply ports 10A, and SiC deposits are generated near the supply ports 10A. When SiC deposits are peeled off, the peeled SiC deposits become a cause of particles. By suppressing the temperature rise of the ceiling 11 and the tapered part 12, an increase in deposits can also be suppressed.

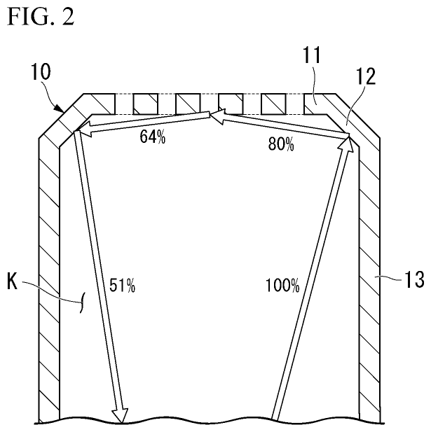

FIG. 2 is a view schematically showing multiple reflection of radiant heat (electromagnetic waves) in the film formation space K. The tapered part 12 is inclined with respect to the ceiling 11. The radiant heat reflected by the tapered part 12 is concentrated toward the ceiling 11. The radiant heat reflected by the ceiling 11 reaches the tapered part 12 again, and is transmitted downward to the furnace body 10. That is, the furnace body 10 has the tapered part 12 so that the radiant heat is multiple-reflected toward the lower side of the furnace body 10. Since the SiC wafer W is placed at the lower position in the furnace body 10, the heating efficiency of the SiC wafer W is improved. SiC having high emissivity (emissivity: 0.8) has a theoretical reflectance of 0.2 (=1.0−emissivity (0.8)). When the inner surfaces of the tapered part 12 and the ceiling 11 are SiC, the radiant heat after being reflected twice is 4% (=0.2×0.2×100%) with respect to that before reflection. Otherwise, TaC having low emissivity (emissivity: 0.2) has a theoretical reflectance of 0.8 (=1.0−emissivity (0.2)). When the inner surfaces of the tapered part 12 and the ceiling 11 are TaC, the radiant heat after being reflected twice is 64% (=0.8×0.8×100%) with respect to that before reflection. That is, by coating the inner surfaces of the tapered part 12 and the ceiling 11 with TaC, the heating efficiency of the SiC wafer W due to multiple reflected radiant heat becomes 10 times or more.

The preferable embodiments of the present invention have been described in detail above. However, the present invention is not limited to the specific embodiments, and various modifications and changes can be made within the scope of the gist of the present invention described in the claims.

### EXAMPLES

### Example 1

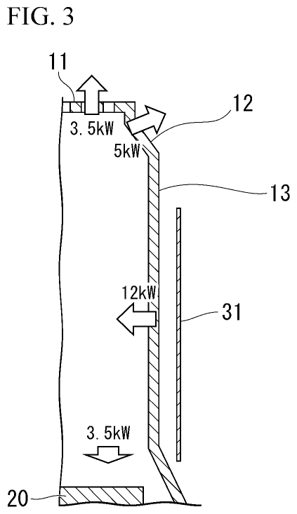

Simulation was performed such that the heat transfer amount at each portion when the temperature of the wafer surface was set to a predetermined temperature was obtained using a SiC chemical vapor deposition device having the same configuration as in FIG. 1. For the simulation, general-purpose FEM thermal analysis software ANSYS Fluent was used. In order to reduce the calculation load, the simulation was performed with only a structure of a half (half in the radial direction) of any cross section passing through the central axis. FIG. 3 is a view showing a simulation result of the first embodiment.

The emissivity of each part of the furnace body in Example 1 was as follows.

Side wall 13: 0.8 (equivalent to SiC coating)

Ceiling 11 and tapered part 12: 0.2 (equivalent to TaC coating)

The first heater 31 was heated, and the heat transfer amount which was transferred from the first heater 31 was obtained. The heat transfer amount which was transferred from the side wall 13 to the inside of the furnace body was 12.0 kW. Of this, 3.5 kW was transferred to the ceiling 11, 5.0 kW was transferred to the tapered part 12, and 3.5 kW was transferred to the placement table 20. That is, 29.2% of the heat transfer amount, which is transferred from the side wall 13 to the inside of the furnace body, was used for heating the SiC wafer placed on the placement table 20.

### Comparative Example 1

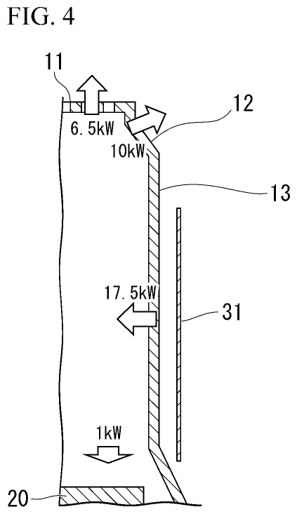

Comparative Example 1 was different from Example 1 only in that the emissivity of the ceiling 11 and the tapered part 12 of the furnace body was set to 0.8. Other conditions were the same as in Example 1. FIG. 4 is a view showing a simulation result of Comparative Example 1. The emissivity of each part of the furnace body in Comparative Example 1 was as follows.

Ceiling 11, Tapered part 12, and Side wall 13: 0.8 (equivalent to SiC coating)

The first heater 31 was heated, and the heat transfer amount which was transferred from the first heater 31 was obtained. The heat transfer amount from the side wall 13 to the inside of the furnace body was 17.5 kW. Of this, 6.5 kW was transferred to the ceiling 11, 10.0 kW was transferred to the tapered part 12, and 1.0 kW was transferred to the placement table 20. That is, 5.7% of the heat transfer amount which is transferred from the side wall 13 to the inside of the furnace body was used for heating the SiC wafer placed on the placement table 20.

The heat transfer amount (17.5 kW) of Comparative Example 1 which is transferred from the side wall 13 to the inside of the furnace body was larger than the heat transfer amount (12.0 kW) of Example 1. This was because the heat transfer amount for causing the temperature of the SiC wafer to be constant was obtained. In other words, in Example 1, the SiC wafer was be heated to a predetermined temperature with a small amount of heat, and therefore the power consumption of the first heater 31 was reduced.

Further, the heat transfer amount (3.5 kW) which is transferred to the ceiling 11 in Example 1 was smaller than the heat transfer amount (6.5 kW) which is transferred to the ceiling 11 in Comparative Example 1. That is, in Example 1, the ceiling 11 is suppressed from increasing to a high temperature, and deposits that cause generation of particles are unlikely to occur.

### Comparative Example 2

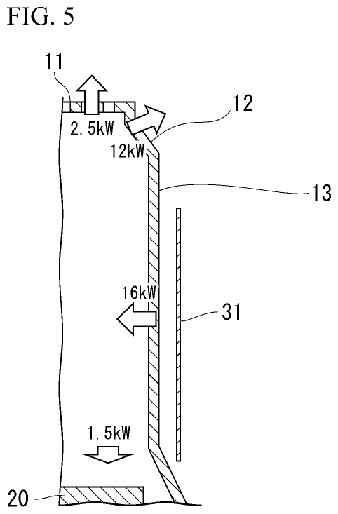

Comparative Example 2 is different from Example 1 only in that the emissivity of the tapered part 12 of the furnace body was set to 0.8. Other conditions were the same as in Example 1. FIG. 5 is a view showing a simulation result according to Comparative Example 2. The emissivity of each part of the furnace body in Comparative Example 2 was as follows.

Side wall 13 and Tapered part 12: 0.8 (equivalent to SiC coating)

Ceiling 11: 0.2 (equivalent to TaC coating)

The first heater 31 was heated, and the heat transfer amount which was transferred from the first heater 31 was obtained. The heat transfer amount which was transferred from the side wall 13 to the inside of the furnace body was 16.0 kW. Of this, 2.5 kW was transferred to the ceiling 11, 12.0 kW was transferred to the tapered part 12, and 1.5 kW was transferred to the placement table 20. That is, 9.4% of the heat transfer amount which is transferred from the side wall 13 to the inside of the furnace body was used for heating the SiC wafer placed on the placement table 20.

The heat transfer amount (16.0 kW) of Comparative Example 2 which is transferred from the side wall 13 to the inside of the furnace body was larger than the heat transfer amount (12.0 kW) of Example 1 and was smaller than the heat transfer amount (17.5 kW) of Comparative Example 1. This is because the heat transfer amount for causing the temperature of the SiC wafer to be constant is obtained. In order to heat the SiC wafer to a predetermined temperature, an amount of heat, which is larger than that in Example 1, was required for Comparative Example 2, and an amount of heat, which is smaller than that in Comparative Example 1, is enough for Comparative Example 2.

Further, the heat transfer amount (2.5 kW) to the ceiling 11 of Comparative Example 2 is smaller than the heat transfer amount (3.5 kW) to the ceiling 11 in Example 1 and the heat transfer amount (6.5 kW) in Comparative Example 1. That is, only in view of preventing the ceiling 11 from becoming high temperature, it is preferable to reduce the emissivity of the ceiling 11.

On the other hand, in Example 1, by reducing the emissivity of parts including the tapered part 12, it is possible to prevent the ceiling 11 from becoming a high temperature, and the heat transfer amount which was transferred from the side wall 13 to the inside of the furnace body can be most efficiently used to heat the SiC wafer.

In this manner, the present invention can obtain the SiC chemical vapor deposition device excellent in power consumption.

### EXPLANATION OF REFERENCES

10 furnace body
10A supply port
10B exhaust port
11 ceiling
12 tapered part
13 side wall
13A first portion
13B second portion
13C third portion
14 bottom part
14A hole
11a, 12a, 13a inner surface
11b, 12b, 13b outer surface
20 placement table
20a placement surface
21 support
22 support shaft
30 heater
31 first heater
31a upper end
32 second heater
100 SiC chemical vapor deposition device
W SiC wafer
K film formation space
G raw material gas

1. A SiC chemical vapor deposition device comprising:
a placement table on which a SiC wafer is placed; and
a furnace body that covers the placement table,
wherein the furnace body has
a side wall,
a ceiling that has a supply port for supplying raw material gas to an inside of the furnace body, covers a periphery of the supply port, and is positioned above the placement table, and
a tapered part that connects together the ceiling and the side wall, and
emissivity of inner surfaces of the ceiling and the tapered part is lower than that of an inner surface of the side wall.

2. The SiC chemical vapor deposition device according to claim 1,
wherein the inner surfaces of the ceiling and the tapered part are coated with TaC.

3. The SiC chemical vapor deposition device according to claim 1,
wherein the inner surface of the side wall is coated with SiC.

4. The SiC chemical vapor deposition device according to claim 1, further comprising:
a heater that surrounds an outer periphery of the side wall in a circumferential direction with an axis which is an imaginary line connecting the placement table and the ceiling, and
an upper end of the heater is placed at a lower position than the ceiling and the tapered part.
